(19) United States
(12) Patent Application Publication
(10) Pub. No.: US 2007/0159245 A1
(43) Pub. Date: Jul. 12, 2007

(54) Apparatus for calibrating non-linearity of radio frequency power amplifier

(75) Inventor: Han-Seok Kim, Seoul (KR)

Correspondence Address: THE FARRELL LAW FIRM, P.C., 333 EARLE OVINGTON BOULEVARD, SUITE 701, UNIONDALE, NY, 11553, US

(73) Assignee: SAMSUNG ELECTRONICS CO., LTD., Suwon-si (KR)

(21) Appl. No.: 11/638,784

(22) Filed: Dec. 14, 2006

(30) Foreign Application Priority Data
Dec. 14, 2005 (KR) 2005-0123011

(51) Int. Cl. H03F 1/26

(52) U.S. Cl. 330/149

(57) ABSTRACT

An apparatus for calibrating the non-linearity of an RF power amplifier is provided. In an amplification apparatus for the RF power amplifier, a main amplification portion up converts an input baseband digital signal to a time variant input analog signal, and amplifies the input analog signal to a power level. A distortion generation portion generates a digital distortion signal using the input baseband digital signal and a reference value, up converts the digital distortion signal to a time variant analog distortion signal, and amplifies the analog distortion signal to the power level. The power combiner generates a distortion-free main amplification signal as a final output signal of the RF power amplifier by adding the main amplification signal received from the main amplifier to the amplified distortion signal.

This application claims priority under 35 U.S.C. § 119 to an application filed in the Korean Intellectual Property Office on Dec. 14, 2005 and assigned Serial No. 2005-123011, the contents of which are incorporated herein by reference.

### BACKGROUND OF THE INVENTION

1. Field of the Invention

The present invention relates generally to a Radio Frequency (RF) power amplifier, and in particular, to an apparatus for calibrating the non-linearity of an RF power amplifier.

2. Description of the Related Art

Typically, an RF input signal is amplified to an intended power level by a main amplifier. A distortion component is inherent to the amplification process due to the non-linearity of a device in the main amplifier. The amplifier output is eventually the sum of the amplified signal and the distortion component in proportion to the input signal. That is, the RF power amplifier does not amplify a signal in a perfect linear fashion. The degree of the distortion is dependent on the type of the device used for the power amplifier, the variation in the amplitude of the input signal, and the structure of the power amplifier. In order to achieve a distortion-free amplified output signal, the linearity of the amplification required for the RF power amplifier must be satisfied by suppressing the distortion generation or eliminating the distorted component.

Negative feedback, predistortion, or a feed-forward linearizer improves the linearity of the entire power amplifier. The concept of predistortion is to generate a signal at the input of the power amplifier, which is in anti-phase with the distorted signal produced by the power amplifier, and thus compensate for the distortion with the generated signal. The feed-forward linearizer extracts an opposite phase component to that of the distortion product, amplifies it, and adds the amplified phase component to the amplifier output, thus compensating for the distortion.

FIG. 1 is a block diagram of a conventional feed-forward linearizer. The feed-forward linearizer out performs other techniques for increasing the linearity of the entire power amplifier, in terms of linearization performance. It includes a main amplifier 101, a first directional coupler 103, a first delay 105, a second directional coupler 107, a second delay 109, a third directional coupler 111, and a distortion amplifier 113.

Referring to FIG. 1, main amplifier 101 receives a non-distorted analog input signal 100 and amplifies analog signal 100. Output 110 of main amplifier 101 includes a distortion component. First direction coupler 103 provides the distorted amplifier output to first delay 105 and a portion of the distorted amplifier output to third directional coupler 111. First delay 105 delays distorted signal 110 for a predetermined time equal to the time taken for a signal 130 output from third directional coupler 111 to pass through distortion amplifier 113.

Second delay 109 receives non-distorted signal 100 like main amplifier 101 and delays input signal 100 for the time taken for input signal 100 to pass through main amplifier 101. Third directional coupler 111 adds delayed input signal 100 received from second delay 109 to distorted signal 110 received from first directional coupler 103. One thing to note here is that third directional coupler 111 adjusts two signals 100 and 110 such that they have the same amplitude but opposite phases, for the addition operation. The opposite phase combining results in only a distortion signal 130 with the opposite phase, eliminating the component of input signal 100. Distortion amplifier 113 amplifies distortion signal 130 received from third directional coupler 111 so that distortion signal 130 has the same amplitude as the distortion component of output signal 110 of main amplifier 101.

Second directional coupler 107 adds distorted signal 110 output from main amplifier 101 delayed by first delay 105 to the amplified distortion signal, thus outputting resulting signal 120. Since the addition compensates distorted signal 110, distortion-free signal 120 is produced at the output of the whole power amplifier.

FIG. 2 is a block diagram of a conventional improved feed-forward linearizer. In order to achieve optimum linearity performance, this feed-forward linearizer further includes a feedback processor 223 and variable circuits 215, 217, 219 and 221 in addition to the structure of the basic feed-forward linearizer illustrated in FIG. 1. To maximize the total linearization property, first attenuator 215 and first phase shifter 217 are provided at the front end of main amplifier 201 and second attenuator 219 and second phase shifter 221 are inserted at the front end of distortion amplifier 213. Feedback processor 223 is further provided to control these circuits 215, 217, 219 and 221.

Referring to FIG. 2, the basic components of the power amplifier, for example, main amplifier 201, distortion amplifier 213, directional couplers 203, 207 and 211, and delays 205 and 209 experience changes in operational characteristics due to environmental changes including temperature and operational voltage, and time-variant changes in the components themselves. To keep the operational state optimal, feedback processor 223 maximizes the total linearization property by controlling first attenuator 215, first phase shifter 217, second attenuator 219, and second phase shifter 221 based on information resulting from monitoring the input and output of the power amplifier. The amplitudes of signals at the input of first and second attenuators 215 and 219 are accurately controlled under the control of feedback processor 223 and the phases of signals at the input of the first and second phase shifters 215 and 219 are accurately controlled under the control of feedback processor 223.

As described above, besides the main amplifier, the conventional feed-forward linearizer additionally uses the distortion amplifier to amplify the distortion signal. The distortion amplifier must be a low-efficiency, high-linearity amplifier to prevent additional distortion of the distortion signal and amplify the distortion signal linearly. As a consequence, the efficiency of the whole power amplifier becomes poorer and that of the linearizer decreases. Due to the transmission loss of the delays of the main signal, the distortion signal in the same phase and the directional couplers that extract and combine the distortion signal, a higher gain and more power are required to achieve the same final output power. Moreover, although a low-loss transmission line is required for implementation of excellent delay circuits, the delay circuits using the transmission line are bulky, thereby increasing the size of the whole power amplifier.

### SUMMARY OF THE INVENTION

An object of the present invention is to substantially solve at least the above problems and/or disadvantages and to provide at least the advantages below. Accordingly, an object of the present invention is to provide an apparatus for calibrating the non-linearity of an RF power amplifier.

Another object of the present invention is to provide an apparatus for improving the linearity of an RF power amplifier by generating a distortion signal out of an input baseband digital signal and reducing the distortion of an output signal using the distorted signal.

The above objects are achieved by providing an apparatus for calibrating the non-linearity of an RF power amplifier.

According to one aspect of the present invention, in an amplification apparatus for an RF power amplifier, a main amplification portion up converts an input baseband digital signal to an input analog signal of a predetermined frequency band, amplifies the input analog signal to a predetermined power level, and outputs the amplified signal as a main amplification signal to a power combiner. A distortion generation portion generates a digital distortion signal using the input baseband digital signal and a predetermined reference value, up converts the digital distortion signal to an analog distortion signal of the predetermined frequency band, amplifies the analog distortion signal to the predetermined power level, and outputs the amplified distortion signal to the power combiner. The power combiner generates a distortion-free main amplification signal by adding the main amplification signal to the amplified distortion signal, and outputs the distortion-free main amplification signal as a final output signal of the RF power amplifier.

### BRIEF DESCRIPTION OF THE DRAWINGS

The above and other objects, features and advantages of the present invention will become more apparent from the following detailed description when taken in conjunction with the accompanying drawings in which:

FIG. 1 is a block diagram of a conventional feed-forward linearizer;

FIG. 2 is a block diagram of a conventional improved feed-forward linearizer;

FIG. 3 is a block diagram of an apparatus for calibrating the non-linearity of an RF power amplifier according to the present invention;

FIG. 4 is a block diagram of a wideband distortion generator according to the present invention;

FIG. 5 is a block diagram of a wideband distortion generator according to the present invention; and

FIG. 6 is a block diagram of a wideband distortion generator according to the present invention.

### DETAILED DESCRIPTION OF THE PREFERRED EMBODIMENTS

Preferred embodiments of the present invention will be described herein below with reference to the accompanying drawings. In the following description, well-known functions or constructions are not described in detail since they would obscure the invention in unnecessary detail.

The present invention provides an apparatus for calibrating the non-linearity of an RF power amplifier.

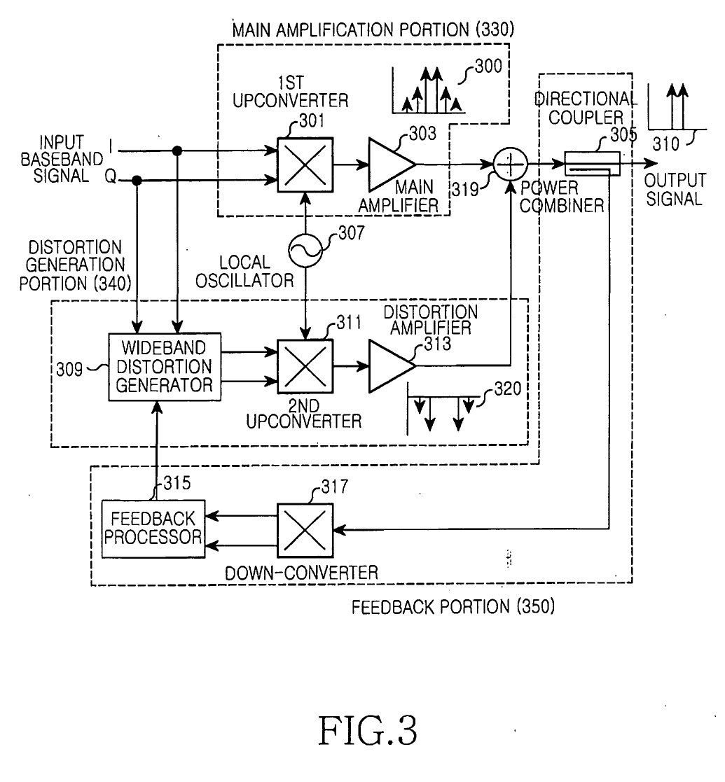

FIG. 3 is a block diagram of an apparatus for calibrating the non-linearity of an RF power amplifier according to the present invention. The calibrating apparatus includes a main amplification portion 330, a distortion generation portion 340, a power combiner 319, and a feedback portion 350. The main amplification portion 330 generates a main amplification signal by upconverting an input baseband signal to an intended frequency band and amplifying the upconverted signal to a predetermined power level. Distortion generation portion 340 generates a distortion signal out of the input baseband signal, upconverts the distortion signal to the intended frequency band, and amplifies the upconverted distortion signal to the predetermined power level. Power combiner 319 compensates for the distortion of the main amplification signal by combining the main amplification signal with the distortion signal, and outputs the distortion-free main amplification signal. Feedback portion 350 feeds back a portion of signal received from main amplification portion 330 to a wideband distortion generator 309, for use in calibrating the distortion signal.

Main amplifier 330 includes a first upconverter 301 and a main amplifier 303. The distortion generation portion 340 includes wideband distortion generator 309, a second upconverter 311, and a distortion amplifier 313. Feedback portion 350 includes a directional coupler 305, a downconverter 317, and a feedback processor 315.

Referring to FIG. 3, first upconverter 301 converts I and Q input baseband digital complex signal, produces a vector-modulated signal from the analog signal, and upconverts the vector-modulated signal to a predetermined frequency band by use of a local oscillator 307. First upconverter 301 may be configured to have a Digital-to-Analog Converter (DAC) and a vector modulator. Main amplifier 303 amplifies the analog signal received from first upconverter 301 to a predetermined power level. Resulting main amplification signal 300 at the output of main amplifier 303 contains a distortion component.

Wideband distortion generator 309 generates a digital distortion signal with which to compensate for the distortion component of main amplification signal 300 using the I and Q input baseband digital complex signal and information about the non-linearity of main amplifier 303. Also, wideband distortion generator 309 corrects the distortion signal based on distortion compensation information received from feedback processor 315 such that the distortion signal has an amplitude proportional to that of distortion component from main amplifier 303 and an opposite phase to that of the distortion component. In general, the distortion component produced from the RF power amplifier appears across a wider band than the bandwidth of the signal to be amplified. Therefore, the distortion signal generated from wideband distortion generator 309 must have a larger bandwidth than that of the input signal by a few times. An external band-pass filter can reduce the distortion component appearing across a wider band than the distortion signal.

Second upconverter 311 converts the digital distortion signal received from wideband distortion generator 309 to an analog distortion signal and upconverts the analog distortion signal to the frequency band of the input signal of main amplifier 303 by use of local oscillator 307. Distortion amplifier 313 amplifies the upconverted analog distortion signal to the power level of the distortion component included in output signal 300 of main amplifier 303. Distortion signal 320 at the output of distortion amplifier 313 has the same amplitude as and the opposite phase to main amplification signal 300.

Power combiner 319 adds main amplification signal 300 to distortion signal 320 and outputs resulting distortion-free signal 310 to directional coupler 305. Directional coupler 305 outputs distortion-free signal 310, i.e. linear amplification signal 310 of the input signal to the output end of the whole power amplifier, and extracts a portion of output signal 310 and sends it to downconverter 317.

Downconverter 317 downconverts received signal 310 to a baseband signal. Feedback processor 315 generates the distortion compensation information using the baseband signal, for use in calibration of the distortion signal, and provides it to wideband distortion generator 309.

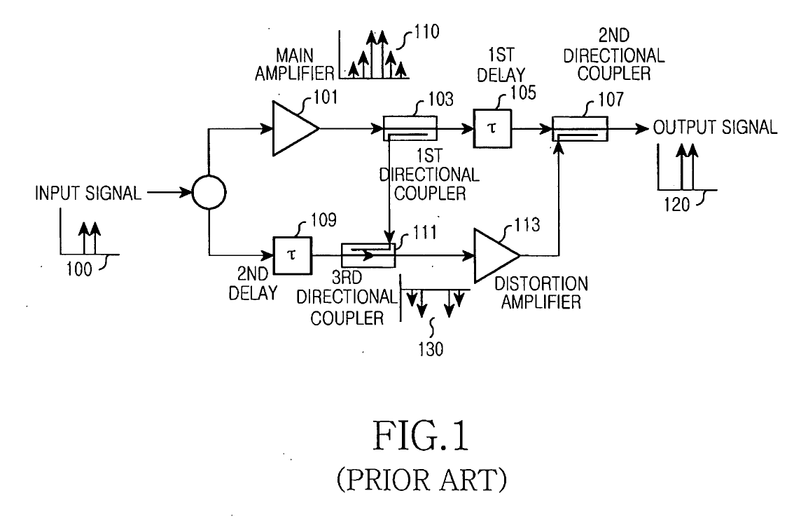

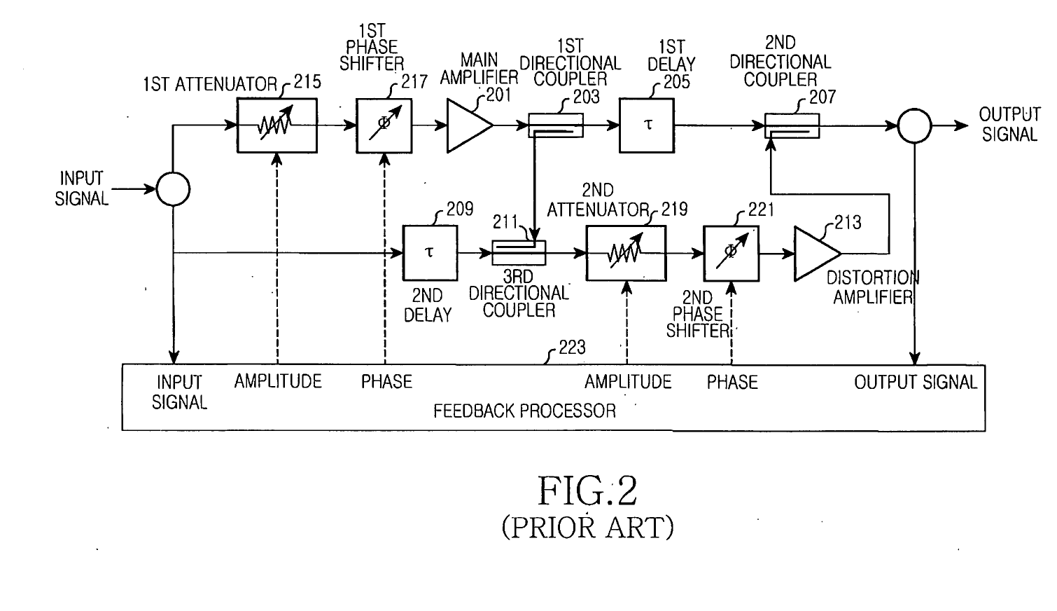

The RF power amplifier so-configured requires less delays and directional couplers, thereby reducing the size of the RF power amplifier, the problem encountered with the conventional technology illustrated in FIGS. 1 and 2, and increased efficiency results.

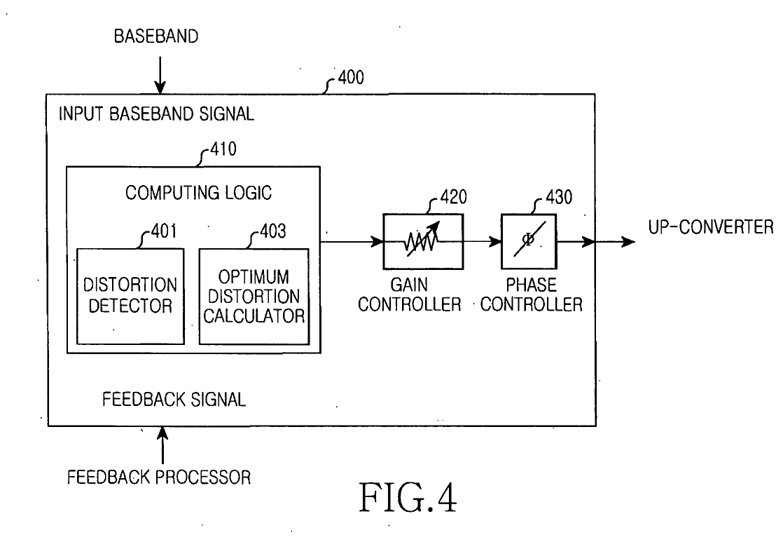

FIG. 4 is a block diagram of a wideband distortion generator according to the present invention. A wideband distortion generator 400 includes a computing logic 410. When needed, it further includes a gain controller 420 and a phase controller 430. Computing logic 410 is so configured as to include a distortion detector 401 and an optimum distortion calculator 403.

Referring to FIG. 4, distortion signal detector 401 in computing logic 410 has a lookup table. Upon receipt of a baseband digital signal, distortion detector 401 detects a distortion signal corresponding to the input signal in the lookup table. Distortion signal values mapped to input signals are theoretically calculated according to the non-linear property of main amplifier 330, or empirically extracted by simulation, or acquired by learning using an adaptive filter structure.

Optimum distortion calculator 403 calculates an optimum distortion signal using the distortion signal received from distortion signal detector 401 and the distortion compensation information received from feedback processor 315, i.e. the feedback information about the non-linearity of the output signal by an adaptive algorithm.

Gain controller 420 controls the gain of the optimum distortion signal, and phase controller 430 controls the phase of the optimum distortion signal received from gain controller 420. Upconverter 311 thus receives the digital distortion signal from wideband distortion generator 400.

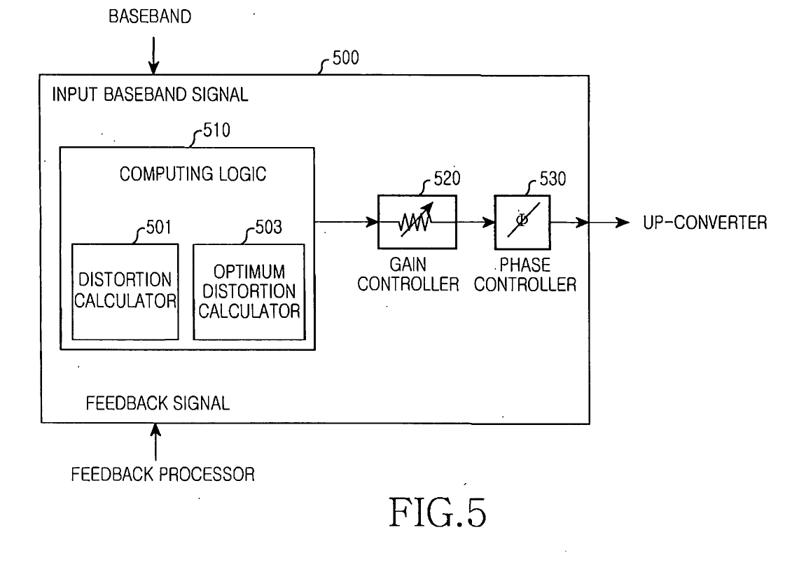

FIG. 5 is a block diagram of a wideband distortion generator according to the present invention. A wideband distortion generator 500 includes a computing logic 510, as with FIG. 4. When needed, it further includes a gain controller 520 and a phase controller 530. Computing logic 510 is so configured as to include a distortion calculator 501 and an optimum distortion calculator 503. Since optimum distortion calculator 503, gain controller 520, and phase controller 530 operate in the same manner as their counterparts 403, 420 and 430 illustrated in FIG. 4, only distortion calculator 501 will be described.

Referring to FIG. 5, distortion calculator 501 of computing logic 510 calculates a distortion component for an input signal in real time based on a non-linear model. Typically, the non-linear property of main amplifier 303 can be modeled as Equation (1).

For any input x, the output y of main amplifier 303 is given as
y=a₁x+a₂x² +a₃x³+ (1)
where aₙ denotes the coefficient of an n^{th}-order term. Specifically, a₁ denotes the linear gain of main amplifier 303 and a₂ and a₃ denote the gains of second-order and third-order distortion components, respectively. The coefficients are determined according to the characteristics of the amplifier device or the operation point and operation scheme of the amplifier. Therefore, the distortion component for the baseband input signal can be calculated directly by modeling the non-linear property of main amplifier 303 and setting the model in distortion calculator 501. Since the distortion component e(x) for the input signal x is the remainder of subtracting the first-order term from Equation (1) to obtain Equation (2),
e(x)=a₂x² +a₃x³ + (2)

The direct calculation of a distortion component for a given input leads to a more accurate result than the use of a lookup table as illustrated in FIG. 4.

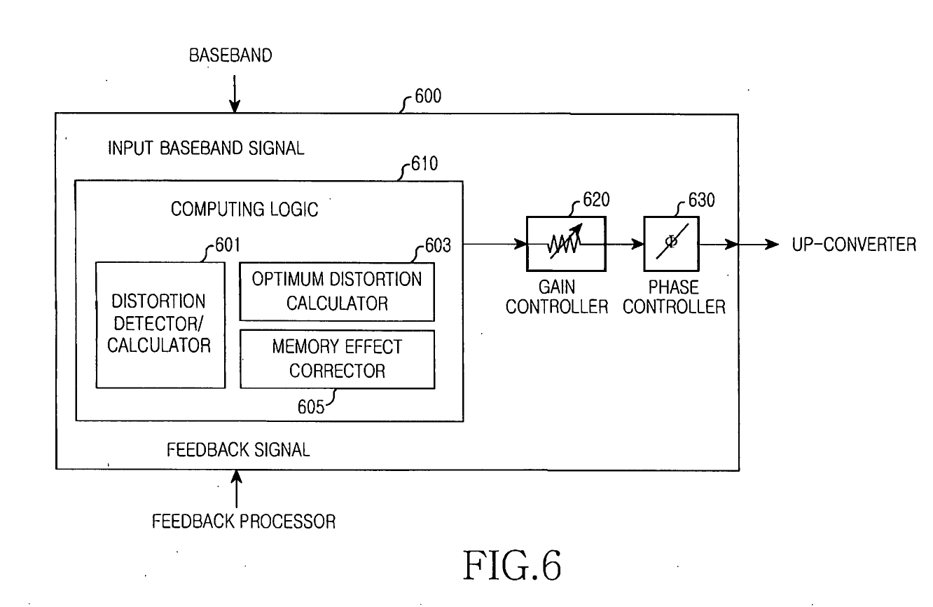

FIG. 6 is a block diagram of a wideband distortion generator according to the present invention. A wideband distortion generator 600 includes a computing logic 610, as with FIG. 4. When needed, it further includes a gain controller 620 and a phase controller 630. The computing logic 610 is so configured as to include a distortion detector 601, an optimum distortion calculator 603, and a memory effect corrector 605. The following description is made only of the memory effect corrector 605 since the other blocks 601, 603, 620 and 630 operate in the same manner as their counterparts illustrated in FIG. 4 or FIG. 5.

Referring to FIG. 6, in computing logic 610, memory effect corrector 605 extracts a distortion component generated by the memory effect. In general, the memory effect of the RF power amplifier is a phenomenon wherein the amplifier output depends not only on a current input signal but also on a previous input due to the non-linear parasitic reactance of the power amplifier device or circuit. The memory effect especially occurs as the thermal factor of the amplifier device changes the amplifier output. This is called the thermal memory effect. The memory effect-caused distortion is severer than distortion produced without the memory effect or with less of the memory effect. Accordingly, it is preferable to consider the memory effect-caused distortion in distortion generation. Memory effect corrector 605 corrects the memory effect-caused distortion component in a distortion signal or distortion component from a distortion detector/calculator 601.

As described above, the present invention provides a linearizer for generating a distortion signal using a baseband digital signal input to an RF power amplifier and reducing the distortion of the output of a main amplifier by combining the distortion signal with the main amplifier output. Therefore, the non-linearity of the RF power amplifier is calibrated, its linearity being improved. Also, the total size of the power amplifier is decreased, efficiency is increased, the amplifier structure is simplified, and linearization of a power amplifier allowing for direct digital control can be achieved. Furthermore, the RF power amplifier becomes cheap and more reliable, and saves operational cost.

While the invention has been shown and described with reference to certain preferred embodiments thereof, it will be understood by those skilled in the art that various changes in form and details may be made therein without departing from the spirit and scope of the invention as further defined by the appended claims.

What is claimed is:

1. An amplification apparatus in a Radio Frequency (RF) power amplifier, comprising:
a main amplification portion for upconverting an input baseband digital signal to a time variant input analog signal, amplifying the input analog signal to a power level, and outputting the amplified signal as a main amplification signal to a power combiner;
a distortion generation portion for generating a digital distortion signal using the input baseband digital signal and a reference value, upconverting the digital distortion signal to a time variant analog distortion signal, amplifying the analog distortion signal to the power level, and outputting the amplified distortion signal to the power combiner; and
the power combiner for generating a distortion-free main amplification signal by adding the main amplification signal to the amplified distortion signal, and outputting the distortion-free main amplification signal as a final output signal of the RF power amplifier.

2. The amplification apparatus of claim 1, wherein the amplified distortion signal has the same amplitude as the distortion of a component included in the main amplification signal and an opposite phase to the phase of the distortion component.

3. The amplification apparatus of claim 1, wherein the main amplification portion comprises:
an upconverter for upconverting the input baseband digital signal to the time variant input analog signal; and
a main amplifier for amplifying the input analog signal to the power level.

4. The amplification apparatus of claim 1, wherein the distortion generation portion comprises:
a wideband distortion generator for generating the digital distortion signal using the input baseband digital signal and the predetermined reference value;
an upconverter for upconverting the digital distortion signal to the time variant analog distortion signal; and
a distortion amplifier for amplifing the analog distortion signal to the power level.

5. The amplification apparatus of claim 1, further comprising a feedback portion for extracting a portion of the final output signal, generating distortion compensation information for correcting the distortion signal, and outputting the distortion compensation information to the distortion generation portion.

6. The amplification apparatus of claim 5, wherein the feedback portion comprises:
a downconverter for extracting the portion of the final output signal and converting the extracted portion to a digital signal; and
a feedback processor for generating the distortion compensation information for correcting the distortion signal using the digital signal.

7. The amplification apparatus of claim 4, wherein the wideband distortion generator comprises:
a distortion detector having a lookup table for the reference value for detecting, upon receipt of the input baseband digital signal, a distortion signal corresponding to the input baseband digital signal in the lookup table; and
an optimum distortion calculator for calculating an optimum distortion signal using the detected distortion signal and feedback information of the final output signal.

8. The amplification apparatus of claim 4, wherein the wideband distortion generator comprises:
a distortion component calculator for modeling the non-linearity of the main amplifier and calculating a distortion component for the input baseband digital signal based on the non-linearity model in real time; and
an optimum distortion calculator for calculating an optimum distortion signal using the calculated distortion component and feedback information of the final output signal.

9. The amplification apparatus of claim 7, wherein the wideband distortion generator further comprises:
a gain controller for controlling the gain of the optimum distortion signal; and
a phase controller for controlling the phase of the optimum distortion signal.

10. The amplification apparatus of claim 7, wherein the wideband distortion generator further comprises a memory effect corrector for compensating for a distortion component caused by a memory effect in the distortion signal.

11. The amplification apparatus of claim 7, wherein the feedback information of the final output signal is the distortion compensation information for correcting the distortion signal.

12. The amplification apparatus of claim 8, wherein the distortion component calculator calculates the distortion component expressed by
e(x)=a₂x² +a₃x³+
where e(x) denotes a distortion component for an input signal x, aₙ denotes the coefficient of an n^{th}-order term, and a₂ and a₃ denote the gains of second-order and third-order distortion components, respectively.

13. The amplification apparatus of claim 3, wherein the reference value is information about the non-linearity of the main amplifier.

14. A power amplifier, comprising:
means for amplifying an input signal and outputting the amplified signal;
means for generating a distortion signal using the input signal and a output feedback signal from the power amplifier output, and amplifying the distortion signal and outputting the amplified distortion signal; and
a power combiner for adding the amplified signal and the amplified distortion signal.

15. The amplifier of claim 14, wherein the amplified distortion signal has the same amplitude as the distortion of a component included in the main amplification signal and an opposite phase to the phase of the distortion component.

16. The amplifier of claim 14, wherein the means for amplifying the input signal comprises:
an upconverter for upconverting the input signal to the time variant input analog signal; and
a main amplifier for amplifying the input analog signal and outputting the amplified signal.

17. The amplifier of claim 14, wherein the means for generating a distortion signal comprises:
a wideband distortion generator for generating the digital distortion signal using the input digital signal and the predetermined reference value;
an upconverter for upconverting the digital distortion signal to the time variant analog distortion signal; and
a distortion amplifier for amplifying the analog distortion signal and outputting the amplified distortion signal.

18. The amplifier of claim 14, further comprising a feedback portion for extracting a portion of the output feedback signal from the power amplifier output, generating distortion compensation information for correcting the distortion signal, and outputting the distortion compensation information to the means for generating a distortion signal.

19. The amplifier of claim 17, wherein the wideband distortion generator comprises:
a distortion detector having a lookup table for the reference value for detecting, upon receipt of the input baseband digital signal, a distortion signal corresponding to the input baseband digital signal in the lookup table; and
an optimum distortion calculator for calculating an optimum distortion signal using the detected distortion signal and feedback information of the final output signal.

20. The amplifier of claim 17, wherein the wideband distortion generator comprises:
a distortion component calculator for modeling the non-linearity of the main amplifier and calculating a distortion component for the input baseband digital signal based on the non-linearity model in real time; and
an optimum distortion calculator for calculating an optimum distortion signal using the calculated distortion component and feedback information of the final output signal.

21. The amplifier of claim 19, wherein the wideband distortion generator further comprises:
a gain controller for controlling the gain of the optimum distortion signal; and
a phase controller for controlling the phase of the optimum distortion signal.
